(19) United States
(12) Patent Application Publication
(10) Pub. No.: US 2015/0187918 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: Jae Hoon PARK, Suwon-Si (KR); Kyung Joon HAN, Suwon-Si (KR); In Hyuk SONG, Suwon-Si (KR); Chang Su JANG, Suwon-Si (KR)

(73) Assignee: SAMSUNG ELECTRO-MECHANICS CO., LTD., Suwon-Si (KR)

(21) Appl. No.: 14/281,365

(22) Filed: May 19, 2014

(30) Foreign Application Priority Data
Dec. 27, 2013 (KR) 10-2013-0165337

(51) Int. Cl. H01L 29/739; H01L 27/082

(52) U.S. Cl. CPC H01L 29/7393; H01L 27/082

(57) ABSTRACT

A power semiconductor device may include: a semiconductor laminate formed by stacking a plurality of semiconductor layers each having an emitter metal layer formed on a top thereof and a collector metal layer formed on a bottom thereof; an insulating layer interposed between the semiconductor layers; and a first external electrode and a second external electrode formed on sides of the semiconductor laminate. The first external electrode is electrically connected to the emitter metal layer, and the second external electrode is electrically connected to the collector metal layer.

### CROSS-REFERENCE TO RELATED APPLICATION

This application claims the benefit of Korean Patent Application No. 10-2013-0165337 filed on Dec. 27, 2013, with the Korean Intellectual Property Office, the disclosure of which is incorporated herein by reference.

### BACKGROUND

The present disclosure relates to a power semiconductor device capable of improving current density.

An insulated gate bipolar transistor (IGBT) is a transistor manufactured to have bipolarity by forming a gate using a metal oxide semiconductor (MOS) and forming a p-type collector layer on a rear surface thereof.

Since power metal oxide semiconductor field effect transistors (MOSFETs) were developed in the related art, these transistors have been used in fields requiring high speed switching characteristics.

However, due to inherent structural limitations of MOSFETs, bipolar transistors, thyristors, gate turn-off (GTO) thyristors, and the like, have been used in fields requiring the application of high levels of voltage thereto.

Since IGBTs have low forward loss and rapid switching speed characteristics, the application of the IGBT has increased in fields to which existing thyristors, bipolar transistors, MOSFETs and the like may not be applied.

An operational principle of an IGBT will be described. In the case in which an IGBT device is turned on, when a voltage applied to an anode is higher than a voltage applied to a cathode and a voltage higher than a threshold voltage of the IGBT is applied to a gate electrode, a polarity of a surface of a p-type body region positioned at a lower end of the gate electrode may be inverted, such that an n-type channel is formed.

An electron current injected into a drift region though the channel induces the injection of a hole current from a high-concentration p-type collector layer positioned in a lower portion of the IGBT, similar to a base current of the bipolar transistor.

Due to the injection of these minority carriers at a high concentration, a process of conductivity modulation, in which conductivity in the drift region increases by several tens to several hundreds of times, occurs.

Unlike the MOSFET, in the IGBT, a level of a resistance component in the drift region may be greatly reduced due to the process of conductivity modulation. Therefore, the IGBT may allow very high levels of voltage to be applied thereto.

Current flowing to the cathode is divided into an electron current flowing through the channel and a hole current flowing through a p-n junction between a p-type body region and an n-type drift region.

Since the IGBT has a pnp structure between the anode and the cathode in a structure of a substrate, the IGBT does not have a diode embedded therein unlike the MOSFET, and thus, a separate diode should be connected in reverse parallel with the IGBT.

In an IGBT serving as a power semiconductor device, current density is one of the most significant characteristics.

An improvement in current density leads to a reduction in chip size, thereby affecting a reduction in a size of a power semiconductor module.

The current density of an IGBT made of silicon (Si) has reached a level of around 600 A/cm². However, it is difficult to increase the current density of the IGBT made of Si beyond 600 A/cm² due to inherent limitations of the material.

Therefore, another method for increasing the current density has been demanded.

The following Related Art Document (Patent Document 1) relates to a semiconductor device.

### RELATED ART DOCUMENT

(Patent Document 1) Korean Patent Laid-Open Publication No. 2008-0033973

### SUMMARY

The present disclosure may provide a power semiconductor device capable of improving current density.

According to an aspect of the present disclosure, a power semiconductor device may include: a semiconductor laminate formed by stacking a plurality of semiconductor layers each having an emitter metal layer formed on a top thereof and a collector metal layer formed on a bottom thereof; an insulating layer interposed between the semiconductor layers; and a first external electrode and a second external electrode formed on sides of the semiconductor laminate, wherein the first external electrode may be electrically connected to the emitter metal layer, and the second external electrode may be electrically connected to the collector metal layer.

The semiconductor layer may have a current density of 100 A/cm².

The semiconductor layer may have a thickness of 30 μm to 150 μm.

The insulating layer may be formed of an epoxy.

The power semiconductor device may further include a side insulating layer disposed between the sides of the semiconductor laminate and the first and second external electrodes.

The power semiconductor device may further include a cover layer formed on at least one of a first surface and a second surface of the semiconductor laminate.

According to another aspect of the present disclosure, a power semiconductor device may include: a semiconductor laminate formed by stacking a plurality of semiconductor layers, tops and bottoms of which are alternately inverted, each semiconductor layer having an emitter metal layer formed on the top thereof and a collector metal layer formed on the bottom thereof; and a first external electrode and a second external electrode formed on sides of the semiconductor laminate, wherein the first external electrode may be electrically connected to the emitter metal layer, and the second external electrode may be electrically connected to the collector metal layer.

The semiconductor layer may have a current density of 100 A/cm³.

The semiconductor layer may have a thickness of 30 μm to 150 μm.

The power semiconductor device may further include a side insulating layer disposed between the sides of the semiconductor laminate and the first and second external electrodes.

The power semiconductor device may further include a cover layer formed on at least one of a first surface and a second surface of the semiconductor laminate.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic cross-sectional view of a power semiconductor device according to an exemplary embodiment of the present disclosure;

FIG. 2 is a schematic cross-sectional view of a semiconductor layer of FIG. 1;

FIG. 3 is a schematic cross-sectional view of a power semiconductor device including a cover layer according to an exemplary embodiment of the present disclosure;

FIG. 4 is a schematic cross-sectional view of a power semiconductor device according to another exemplary embodiment of the present disclosure; and

FIG. 5 is a schematic cross-sectional view of a power semiconductor device including a cover layer according to another exemplary embodiment of the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be configured as any one of a power metal oxide semiconductor field effect transistor (MOSFET), an insulated gate bipolar transistor (IGBT), a thyristor, and devices similar thereto. Most of the new technologies disclosed herein will be described based on the IGBT. However, several exemplary embodiments of the present disclosure are not limited to the IGBT. The present inventive concept may also be applied to other types of power switch technology including power MOSFETs and several types of thyristors. Further, several exemplary embodiments of the present disclosure will be described as including specific p-type and n-type regions. However, conductivity types of several regions disclosed herein may be similarly applied to devices having conductivity types opposite thereto.

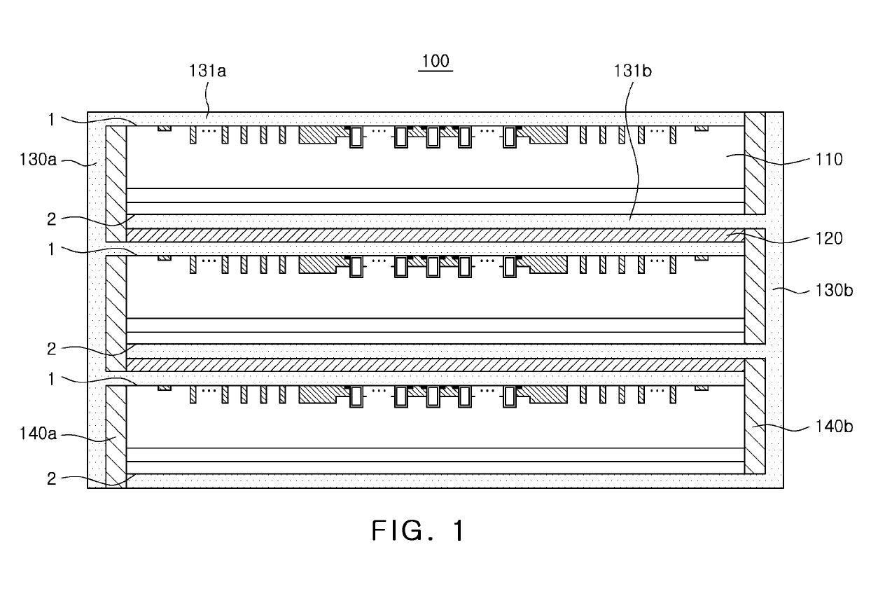

FIG. 1 is a schematic cross-sectional view of a power semiconductor device according to an exemplary embodiment of the present disclosure.

A power semiconductor device 100 according to an exemplary embodiment of the present disclosure will be described with reference to FIG. 1. The power semiconductor device 100 according to this exemplary embodiment of the present disclosure may include a semiconductor laminate, an insulating layer 120, and first and second external electrodes 130a and 130b.

The semiconductor laminate may be formed by stacking a plurality of semiconductor layers 110.

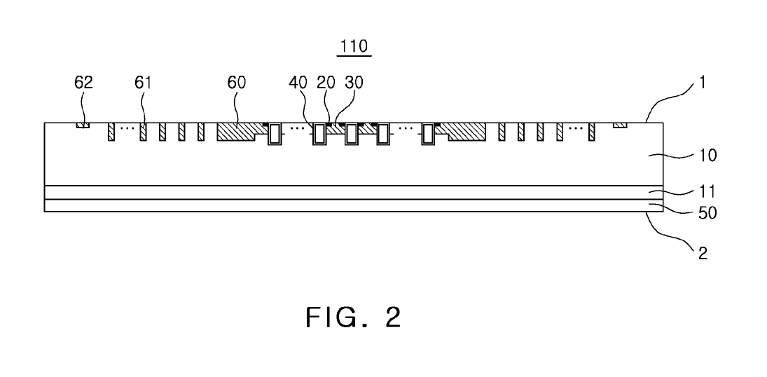

Hereinafter, a structure of the semiconductor layer 110 will be described with reference to FIG. 2.

FIG. 2 is a schematic cross-sectional view of the semiconductor layer 110 of FIG. 1.

A structure of the semiconductor layer 110 will be described with reference to FIG. 2. The semiconductor layer 110 may include a drift region 10, a body region 20, an emitter region 30, a collector region 50, and a trench 40 penetrating from the emitter region 30 to the drift region 10.

The semiconductor layer 110 may have a first surface 1 and a second surface 2.

An emitter metal layer 131a may be formed on the first surface 1 to be electrically connected to the emitter region 30, and a collector metal layer 131b may be formed on the second surface 2 to be electrically connected to the collector region 50.

The drift region 10 may be formed by implanting n-type impurities at a low concentration.

Therefore, the drift region 10 may be relatively thick in order to maintain a breakdown voltage of the power semiconductor device.

The drift region 10 may further include a buffer region 11 formed therebelow.

The buffer region 11 may be formed by implanting n-type impurities into a lower portion of the drift region 10.

The buffer region 11 may serve to block extension of a depletion region of the power semiconductor device, thereby assisting in maintaining a breakdown voltage of the power semiconductor device.

Therefore, in the case in which the buffer region 11 is formed, a thickness of the drift region 10 may be decreased, whereby the power semiconductor device may be miniaturized.

The body region 20 may be formed by implanting p-type impurities into an upper portion of the drift region 10.

The body region 20 may have a p-type conductivity to form a p-n junction with the drift region 10.

The emitter region 30 may be formed by implanting n-type impurities at a high concentration into an upper portion of the body region 20.

The trench 40 may be formed to extend from the emitter region 30 to the drift region 10 through the body region 20.

That is, the trench 40 may penetrate from the emitter region 30 into a portion of the drift region 10.

The trenches 40 may be elongated in one direction and may be arranged at predetermined intervals in a direction perpendicular to one direction.

The trench 40 may have a gate insulating layer formed formed in a region in which it contacts the drift region 10, the body region 20, and the emitter region 30.

The gate insulating layer may be formed of a silicon oxide (SiO₂), but is not limited thereto.

The trench 40 may be filled with a conductive material.

The conductive material may be a polysilicon (poly-Si) or a metal, but is not limited thereto.

The conductive material may be electrically connected to a gate electrode (not shown) to control an operation of the power semiconductor device 100 according to the exemplary embodiment of the present disclosure.

In the case in which a positive voltage is applied to the conductive material, a channel may be formed in the body region 20.

In detail, in the case in which the positive voltage is applied to the conductive material, electrons present in the body region 20 may be drawn toward the trench 40 and be collected around the trench 40, thereby forming the channel.

That is, electrons and holes may be recombined with each other due to a p-n junction, such that the trench 40 draws the electrons toward a depletion region in which carriers are not present to thereby form the channel, whereby a current may flow through the channel.

The collector region 110 may be formed by implanting p-type impurities into a lower portion of the drift region 10 or the buffer region 11.

In the case in which the power semiconductor device is an IGBT, the collector region 50 may provide holes to the power semiconductor device.

Due to injection of the holes, which are minority carriers, at a high concentration, a conductivity modulation in which conductivity in the drift region is increased by several tens to several hundreds of times occurs.

In the case in which the power semiconductor device is an MOSFET, the collector region 50 may have an n-type conductivity.

There is a limitation in a density of current that can flow in a single semiconductor layer 110.

Specifically, the current density of a power semiconductor device made of silicon (Si) has reached a level of around 600 A/cm².

However, it is difficult to increase the current density of the power semiconductor device beyond 600 A/cm² by only using a single semiconductor layer due to inherent limitations of the material.

In addition, in the case in which the power semiconductor device 100 has the current density of 600 A/cm² by using a single semiconductor layer, heating in the power semiconductor device 100 may become severe, and when latch-up or short-circuit occurs, the power semiconductor device is most likely to be destroyed.

The structure of the power semiconductor device 100 according to the exemplary embodiment of the present disclosure will be described in detail with reference to FIG. 1. The power semiconductor device 100 according to this exemplary embodiment of the present disclosure may include a semiconductor laminate formed by stacking the plurality of semiconductor layers 110 each having the emitter metal layer 131a formed on the top thereof and the collector metal layer 131b formed on the bottom thereof; the insulating layer 120 interposed between the semiconductor layers 110; and the first and second external electrodes 130a and 130b formed at sides of the semiconductor laminate, wherein the first external electrode 130a may be electrically connected to the emitter metal layer 131a and the second external electrode 130b may be electrically connected to the collector metal layer 131b.

That is, the power semiconductor device 100 according to the exemplary embodiment of the present disclosure may be formed by stacking the plurality of semiconductor layers 110, thereby achieving increased current density.

That is, the current density of the power semiconductor device 100 may be increased by stacking two or more semiconductor layers 110.

For example, in the case in which a current density of 600 A/cm² is required, the power semiconductor device 100 may be manufactured by stacking six semiconductor layers 110, each of which has a current density of 100 A/cm².

Alternatively, in the case in which a current density of 600 A/cm² is required, the power semiconductor device 100 may be manufactured by stacking three semiconductor layers 110, each of which has a current density of 200 A/cm².

The semiconductor layer 110 may have a thickness of 30 μm to 150 μm.

In the case in which the semiconductor layer 110 has a thickness of 30 μm or less, a breakdown voltage of each semiconductor layer 110 may be dropped to 200V or less. In the case in which the semiconductor layer 110 has a thickness of 150 μm or greater, a total thickness of the semiconductor laminate is significantly increased, and thus, it is difficult to use such a thick semiconductor laminate in a semiconductor module.

Therefore, in order to secure the breakdown voltage and achieve miniaturization, the thickness of the semiconductor layer 110 may be 30 μm to 150 μm.

Since the density of current flowing in each semiconductor layer 110 is lowered as compared with the related art, heat generated in the device may also be sharply decreased.

Therefore, the power semiconductor device 100 according to the exemplary embodiment of the present disclosure may have high robustness against latch-up, whereby reliability of the power semiconductor device 100 may be significantly improved.

The insulating layer 120 may be interposed between the emitter metal layer 131a and the collector metal layer 131b to insulate the emitter metal layer 131a and the collector metal layer 131b from each other.

In addition, the insulating layer 120 may adhere the emitter metal layer 131a and the collector metal layer 131b to each other so that the semiconductor layers 110 are adhered to each other to thereby form the semiconductor laminate.

The insulating layer 120 may be formed of an epoxy based insulator, but is not limited thereto.

The first external electrode 130a and the second external electrode 130b may be electrically connected to the emitter metal layer 131a and the collector metal layer 131b, respectively.

The first and second external electrodes 130a and 130b may be formed at the sides of the semiconductor laminate and may be formed by applying a conductive paste to the semiconductor laminate.

The conductive paste may be formed by mixing a conductive powder such as silver and copper having excellent conductivity with a resin.

The first external electrode 130a is not electrically connected to the collector metal layer 131b and the second external electrode 130b is not electrically connected to the emitter metal layer 131a.

To this end, side insulating layers 140a and 140b may be formed between the first external electrode 130a and the semiconductor laminate and between the second external electrode 130b and the semiconductor laminate, respectively.

The side insulating layers 140a and 140b may be formed of an epoxy.

The power semiconductor device 100 according to the exemplary embodiment of the present disclosure may further include a gate via (not shown) electrically connected to the trench 40 of the semiconductor layer 110.

The gate via 40 may be electrically connected to the trench 40 of each layer by stacking the semiconductor layers 110, forming a via in a portion in which a gate electrode is to be formed, and filling the via with a conductive material.

Since the gate electrode is electrically connected to a gate bus line and the plurality of trenches 40 are electrically connected to the gate bus line, an operation of the power semiconductor device 100 may be controlled by adjusting a level of voltage applied to the gate via.

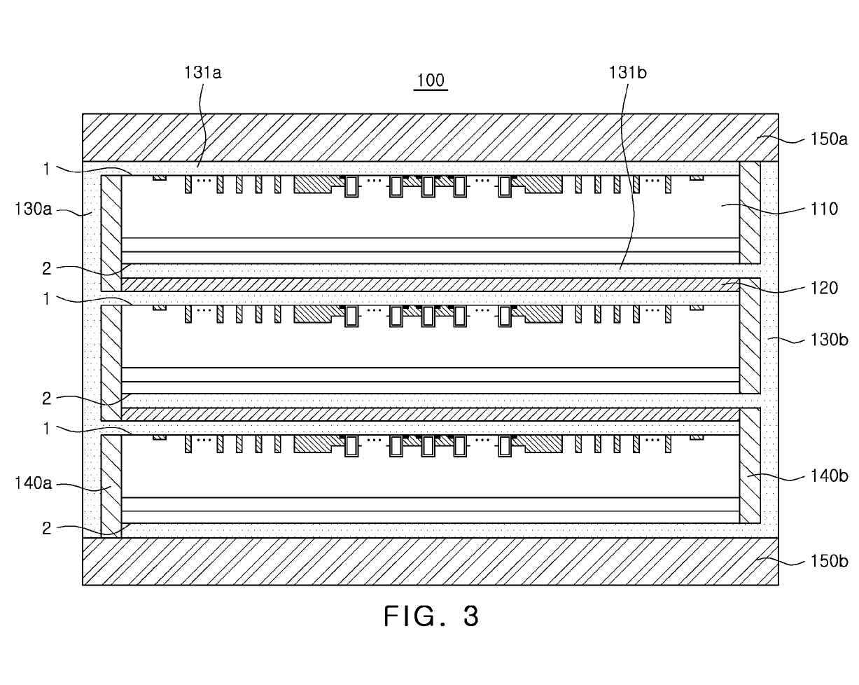

FIG. 3 is a schematic cross-sectional view of a power semiconductor device including a cover layer according to an exemplary embodiment of the present disclosure.

Referring to FIG. 3, the power semiconductor device 100 according to this exemplary embodiment of the present disclosure may have cover layers 150a and 150b formed in at least one of upper and lower portions thereof.

The cover layers 150a and 150b may be formed of an epoxy, but are not limited thereto.

The cover layers 150a and 150b may prevent a conductive foreign object from being introduced into the semiconductor laminate.

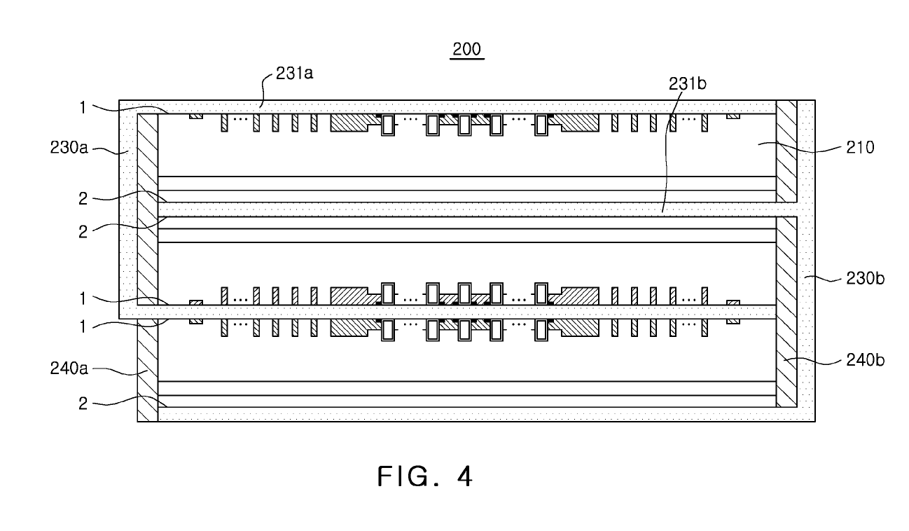

FIG. 4 is a schematic cross-sectional view of a power semiconductor device according to another exemplary embodiment of the present disclosure.

Elements of a power semiconductor device 200 according to this exemplary embodiment, the same as those of the power semiconductor device 100 according to the previous exemplary embodiment, will be omitted.

A structure of the power semiconductor device 200 according to this exemplary embodiment of the present disclosure will be described with reference to FIG. 4. The power semiconductor device 200 according to this exemplary embodiment of the present disclosure may include a semiconductor laminate formed by stacking a plurality of semiconductor layers 210, tops and bottoms of which are alternately inverted, each semiconductor layer having an emitter metal layer 231a formed on the top thereof and a collector metal layer 231b formed on the bottom thereof; and first and second external electrodes 230a and 230b formed at sides of the semiconductor laminate, wherein the first external electrode 230a may be electrically connected to the emitter metal layer 231a and the second external electrode 230b may be electrically connected to the collector metal layer 231b.

The power semiconductor device 200 will be described with reference to a structure of three semiconductor layers 210 sequentially stacked as illustrated in FIG. 4.

In FIG. 4, a lowermost first semiconductor layer 210 may have the collector metal layer 231b formed on a second surface 2 thereof and may have the emitter metal layer 231a formed on a first surface 1 thereof.

A second semiconductor layer 210 positioned on the lowermost semiconductor layer 210 may be formed by being inverted with respect to the lowermost semiconductor layer 210 in a height direction.

That is, a first surface of the second semiconductor layer 210 may be disposed to contact the emitter metal layer 231a and a second surface 2 thereof may be disposed to contact another collector metal layer 231b.

A third semiconductor layer 210 may be formed by being inverted with respect to the second semiconductor layer 210 in a height direction.

That is, the third semiconductor layer 210 may be stacked in the same direction as that of the first semiconductor layer 210.

Therefore, a second surface 2 of the third semiconductor layer 210 may be disposed to contact the collector metal layer 231b in contact with the second semiconductor layer 210, and a first surface 1 thereof may be disposed to contact another emitter metal layer 231a.

That is, since the power semiconductor device 200 according to this exemplary embodiment of the present disclosure does not need to have an insulating layer disposed between the semiconductor layers in the semiconductor laminate, the thickness of the power semiconductor device 200 may be significantly decreased.

In order to form the semiconductor laminate without the insulating layer, the emitter metal layer 231a and the collector metal layer 231b may include a metal layer formed of a conductive paste.

Specifically, the emitter metal layer 231a and the collector metal layer 231b may be obtained by forming a thin film by a deposition method, a sputtering method, or the like, and applying a conductive paste thereto, and then the semiconductor layers 210 may be stacked such that the tops and bottoms thereof may be alternately inverted in the above-described manner.

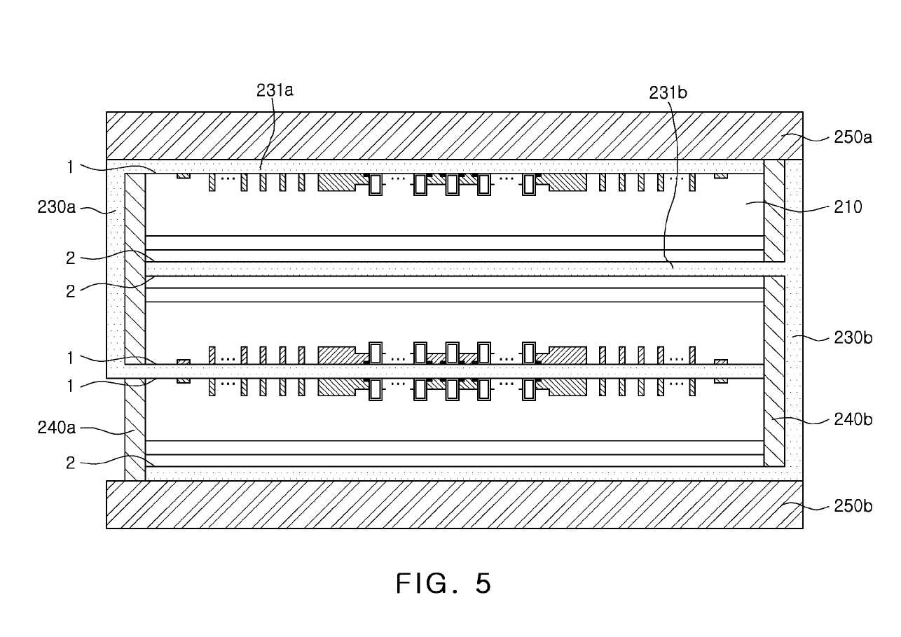

FIG. 5 is a schematic cross-sectional view of a power semiconductor device including a cover layer according to another exemplary embodiment of the present disclosure.

Referring to FIG. 5, the power semiconductor device 200 according to this exemplary embodiment of the present disclosure may have cover layers 250a and 250b formed in at least one of upper and lower portions thereof.

The cover layers 250a and 250b may be formed of an epoxy, but are not limited thereto.

The cover layers 250a and 250b may prevent a conductive foreign object from being introduced into the semiconductor laminate.

As set forth above, according to exemplary embodiments of the present disclosure, a power semiconductor device may have improved current density by stacking a plurality of semiconductor layers.

In addition, a low level of current flows in the semiconductor layers as compared with the related art, such that an amount of heat is decreased and the possibility of destruction of the power semiconductor device due to latch-up is significantly decreased, whereby reliability of the power semiconductor device may be improved.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a semiconductor laminate including a plurality of semiconductor layers each having an emitter metal layer disposed on a top thereof and a collector metal layer disposed on a bottom thereof;
an insulating layer interposed between the semiconductor layers; and
a first external electrode and a second external electrode disposed on sides of the semiconductor laminate,
wherein the first external electrode is electrically connected to the emitter metal layer, and
the second external electrode is electrically connected to the collector metal layer.

2. The power semiconductor device of claim 1, wherein the semiconductor layer has a current density of 100 A/cm².

3. The power semiconductor device of claim 1, wherein the semiconductor layer has a thickness of 30 μm to 150 μm.

4. The power semiconductor device of claim 1, wherein the insulating layer is formed of an epoxy.

5. The power semiconductor device of claim 1, further comprising a side insulating layer disposed between the sides of the semiconductor laminate and the first and second external electrodes.

6. The power semiconductor device of claim 1, further comprising a cover layer formed on at least one of a first surface and a second surface of the semiconductor laminate.

7. A power semiconductor device, comprising:
a semiconductor laminate formed by stacking a plurality of semiconductor layers, tops and bottoms of which are alternately inverted, each semiconductor layer having an emitter metal layer formed on the top thereof and a collector metal layer formed on the bottom thereof; and
a first external electrode and a second external electrode formed on sides of the semiconductor laminate,
wherein the first external electrode is electrically connected to the emitter metal layer, and
the second external electrode is electrically connected to the collector metal layer.

8. The power semiconductor device of claim 7, wherein the semiconductor layer has a current density of 100 A/cm².

9. The power semiconductor device of claim 7, wherein the semiconductor layer has a thickness of 30 μm to 150 μm.

10. The power semiconductor device of claim 7, further comprising a side insulating layer disposed between the sides of the semiconductor laminate and the first and second external electrodes.

11. The power semiconductor device of claim 7, further comprising a cover layer formed on at least one of a first surface and a second surface of the semiconductor laminate.
